(19) United States
(12) Patent Application Publication
(10) Pub. No.: US 2012/0127044 A1
(43) Pub. Date: May 24, 2012

(54) PORTABLE WIRELESS DEVICE

(75) Inventors: Nobuharu Mashima, Toyama (JP); Yoshio Koyanagi, Kanagawa (JP); Noriyoshi Sato, Kanagawa (JP)

(73) Assignee: PANASONIC CORPORATION, Osaka (JP)

(21) Appl. No.: 13/388,423

(22) PCT Filed: Feb. 19, 2010
(86) PCT No.: PCT/JP2010/001095

§ 371 Date: Feb. 1, 2012

(30) Foreign Application Priority Data
Aug. 7, 2009 (JP) 2009-184693

(51) Int. Cl. H01Q 1/24; H05K 5/02

(52) U.S. Cl. 343/702; 361/752

(57) ABSTRACT

Provided is a portable wireless device capable of preventing deterioration in performance of an antenna caused by reverse phase current. The portable wireless device (100) comprises at least two box-shaped housings each of which is formed by fitting respective annular fitting surfaces of two cases. Further, in the portable wireless device (100), a first circuit board (110) is provided in a first housing (101). A second circuit board (115) is provided in a second housing (102). A signal line (119) electrically connects the first circuit board (110) and the second circuit board (115). A waterproofing packing (116) has an annular shape, and is provided between the fitting surfaces of the two cases and held by the two cases which constitute the second housing (102). A conductive element (118) is integrally formed with the waterproofing packing (116), electrically connected to an end of the second circuit board (115), and electrically connected to the signal line (119).

### TECHNICAL FIELD

The present invention relates to a portable radio device. More particularly, the present invention relates to a portable radio device that is equipped with a plurality of casings and has a waterproof structure.

### BACKGROUND ART

Conventionally, a portable radio device equipped with two or more casings and a signal line for electrically connecting circuit boards to each other in each casing, has been known. In such a portable radio device, since a signal line has a strong antenna current distribution, the antenna current flowing through the signal line significantly influences antenna performance.

In addition, conventionally, a position for connecting the above signal line to the circuit board is not the end of the circuit board but the inner side of the circuit board in terms of manufacturing or packaging. In this case, there is a problem that, since the signal line and the circuit board overlap in vertical direction, a reverse-phase current may flow in the signal line and the circuit board and the antenna performance may be deteriorated. In addition, since the phase of the antenna current flowing through the signal line vary depending on the length of the signal line, the influence on the antenna performance is also different, so that it is difficult to ensure desired antenna performance.

Therefore, in the portable radio device described above, it is possible to improve the antenna performance by minimizing generation of the reverse-phase current and controlling the antenna current flowing through the signal line.

In addition, conventionally, the portable radio device disclosed in Patent Literature 1 has been known as the portable radio device for controlling the antenna current. The portable radio device disclosed in Patent Literature 1 has a casing dipole configuration and controls the antenna current flowing through a hinge metal section, by providing a sheet metal combined with the hinge metal section serving as an antenna element.

### CITATION LIST

### Patent Literature

### PTL 1

### Japanese Patent Application Laid-open No. 2005-236396

### SUMMARY OF INVENTION

### Technical Problem

However, in Patent Literature 1, there has been a problem that, since it is not possible to control the antenna current flowing through the signal line connecting the upper and lower casings, the reverse-phase current may flow in the signal line and the circuit board, and the antenna performance may be deteriorated.

It is therefore an object of the present invention to provides a portable radio device capable of preventing deterioration of the antenna performance due to the reverse-phase current.

### Solution to Problem

The portable radio device of the present invention that includes two or more box-shaped casings formed by fitting two cases at a mating surface that is annular, employs a configuration having: a first circuit board provided in the first casing, a second circuit board provided in the second casing, a signal line that electrically connects the first circuit board and the second circuit board, a first packing that is annular and is interposed between the first case and the second case on the mating surface between the first case and the second case forming the second casing, and a first conductive element integrated with the first packing, electrically connected to an end of the second circuit board, and electrically connected to the signal line on the mating surface.

### ADVANTAGEOUS EFFECTS OF INVENTION

According to the present invention, it is possible to prevent deterioration of the antenna performance due to the reverse-phase current,

### BRIEF DESCRIPTION OF DRAWINGS

FIG. 1 is a plan view illustrating a portable radio device in an opened state according to Embodiment 1 of the present invention;

FIG. 2 is a perspective view illustrating the main part of the portable radio device describing the flow of the antenna current when the conductive element according to Embodiment 1 of the present invention is not provided;

FIG. 3 is a side view illustrating the main part of the portable radio device describing the flow of the antenna current when the conductive element according to Embodiment 1 of the present invention is not provided;

FIG. 4 is a perspective view illustrating the main part of the portable radio device for describing the flow of the antenna current when the conductive element according to Embodiment 1 of the present invention is provided;

FIG. 5 is a plan view illustrating the portable radio device in an opened state according to Embodiment 2 of the present invention;

FIG. 6 is a perspective view illustrating the main part of the portable radio device describing the flow of the antenna current when the conductive element according to Embodiment 2 of the present invention is not provided;

FIG. 7 is a side view illustrating the main part of the portable radio device describing the flow of the antenna current when the conductive element according to Embodiment 2 of the present invention is not provided;

FIG. 8 is a perspective view illustrating the main part of the portable radio device describing the flow of the antenna current when the conductive element according to Embodiment 2 of the present invention is provided;

FIG. 9 is a plan view illustrating the portable radio device in an opened state according to Embodiment 3 of the present invention; and

FIG. 10 is a plan view illustrating the portable radio device in an opened state according to Embodiment 4 of the present invention.

### DESCRIPTION OF EMBODIMENTS

Hereinafter, embodiments of the present invention will be described in detail with reference to the accompanying drawings.

### Embodiment 1

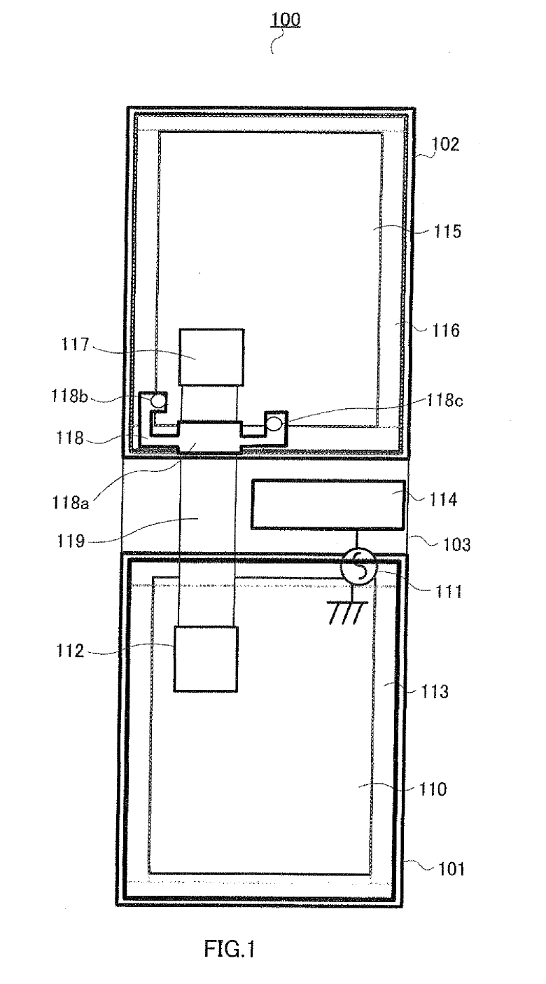

FIG. 1 is a plan view illustrating portable radio device 100 in an opened state according to Embodiment 1 of the present invention.

Portable radio device 100 is mainly formed by first casing 101, second casing 102, hinge section 103, and signal line 119.

First casing 101 includes first circuit board 110, power feeding section 111, connector 112, and waterproof packing 113. Second casing 102 includes second circuit board 115, waterproof packing 116, connector 117, and conductive element 118. In addition, hinge section 103 includes hinge metal section 114. Hereinafter, each configuration will be described in detail.

First casing 101 has a substantially box shape formed by fitting two cases at an annular mating surface and foldably connected to second casing 102 through hinge section 103. Specifically, the state of first casing 101 changes from a closed state (not illustrated) in which first and second casings 101 and 102 are vertically overlapped to an opened state of FIG. 1 or from the opened state of FIG. 1 to the closed state. First casing 101 has first circuit board 110 therein. First casing 101 includes waterproof packing 113 provided in the mating surface where two cases are fitted, and interposed by two cases.

Second casing 102 has a substantially box shape formed by fitting two cases at an annular mating surface and foldably connected to first casing 101 through hinge section 103. Specifically, the state of second casing 102 changes from a closed state (not illustrated) in which first and second casings 101 and 102 are vertically overlapped to an opened state of FIG. 1 or from the opened state of FIG. 1 to the closed state. Second casing 102 has second circuit board 115 therein. Second casing 102 is provided in the mating surface where two cases are fitted and includes waterproof packing 116 interposed by two cases. Second casing 102 includes conductive element 118 integrated with waterproof packing 116 in hinge section 103 side.

Hinge section 103 connects first and second casings 101 and 102 in a rotatable manner. Hinge section 103 has hinge metal section 114 therein.

First circuit board 110 is provided across substantially the entire surface of the inner side of first casing 101. In addition, first circuit board 110 includes power feeding section 111. Connector 112 is mounted on first circuit board 110, and first circuit board 110 is electrically connected to second circuit board 115 through connector 117, signal line 119, and connector 112.

Power feeding section 111 is provided in first circuit board 110 and feeds electricity to hinge metal section 114 to excite hinge metal section 114.

Connector 112 is mounted on first circuit board 110 to electrically connect signal line 119 and first circuit board 110. Connector 112 is located in an inner side than waterproof packing 113 of first casing 101 and is mounted on first circuit board 110.

Waterproof packing 113 has an annular shape and is provided in the mating surface where two cases of first casing 101 are fitted. Waterproof packing 113 hermitically seals the gap between the two case formed when the two cases are fitted. Waterproof packing 113 is formed of a material having an elastic force that can reliably and hermetically seal the gap between two fitted cases.

Hinge metal section 114 serves as an antenna by providing in the inner side of hinge section 103 and electricity being fed from power feeding section 111.

Second circuit board 115 is provided across substantially the entire surface of the inner side of second casing 102. Connector 117 is mounted on second circuit board 115, and second circuit board 115 is electrically connected to first circuit board 110 through connector 112, signal line 119, and connector .117. Second circuit board 115 is electrically connected to conductive element 118 in the end of hinge section 103 side.

Waterproof packing 116 has an annular shape and is provided in the mating surface where two cases of second casing 102 are fitted. In addition, waterproof packing 116 hermitically seals the gap between the two cases formed when two cases are fitted. Waterproof packing 116 is formed of a material having an elastic force that can reliably and hermetically seal the gap between two fitted cases. Moreover, waterproof packing 116 is provided integrally with conductive element 118, and conductive element 118 is firmly connected to signal line 119 by pressedly bonding conductive element 118 and signal line 119 using the elastic force.

Connector 117 is mounted on second circuit board 115, and is electrically connected to signal line 119 and second circuit board 115. Connector 117 is located in the inner side than waterproof packing 116 of second casing 102 and is mounted on second circuit board 115.

Conductive element 118 is formed, for example, using a printed pattern of a flexible printed circuit (hereinafter, referred to as “FPC”), and is provided integrally with waterproof packing 116 in second casing 102. Conductive element 118 is electrically connected to signal line 119 on the mating surface of the case where two cases of second casing 102 are fitted. Conductive element 118 is electrically connected to the end of second circuit board 115. Conductive element 118 includes wide-width section 118a formed to have a wide width and electrically connected to signal line 119 and connection ends 118b and 118c that horizontally extend from wide width section 118a and are electrically connected to the end of second circuit board 115.

Signal line 119 made of, for example, FPC is electrically connected to first circuit board 110 through connector 112 and is electrically connected to second circuit board 115 through connector 117. Specifically, signal line 119 is electrically connected to first circuit boards 110 and second circuit boards 115. Signal line 119 is electrically connected to conductive element 118. In this case, conductive element 118 may be electrically connected to signal line 119 directly or equivalently by capacitively coupling them through a capacitor.

Hereinbefore, the configuration of portable radio device 100 has been described.

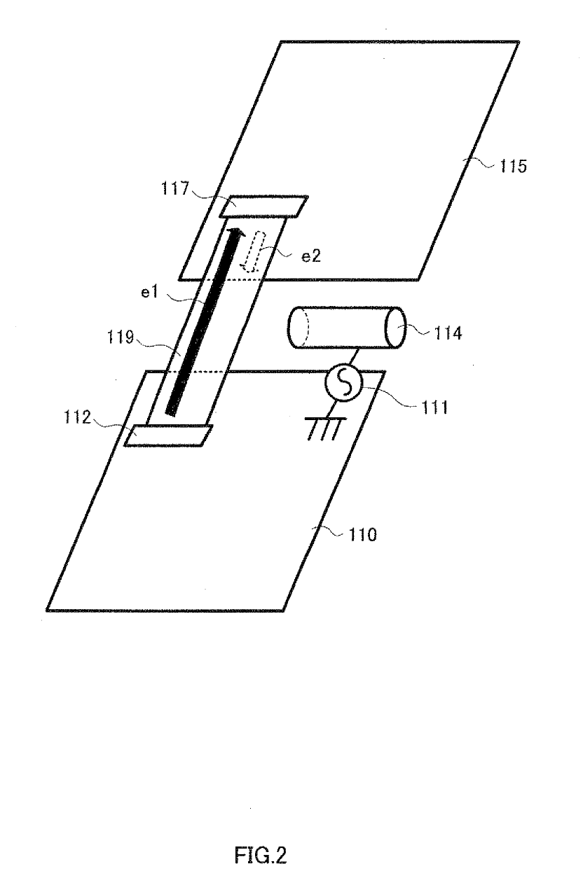

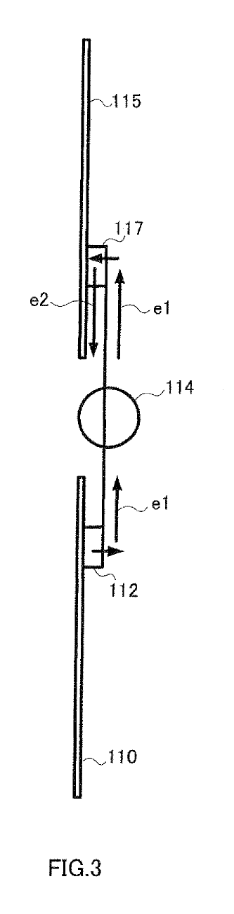

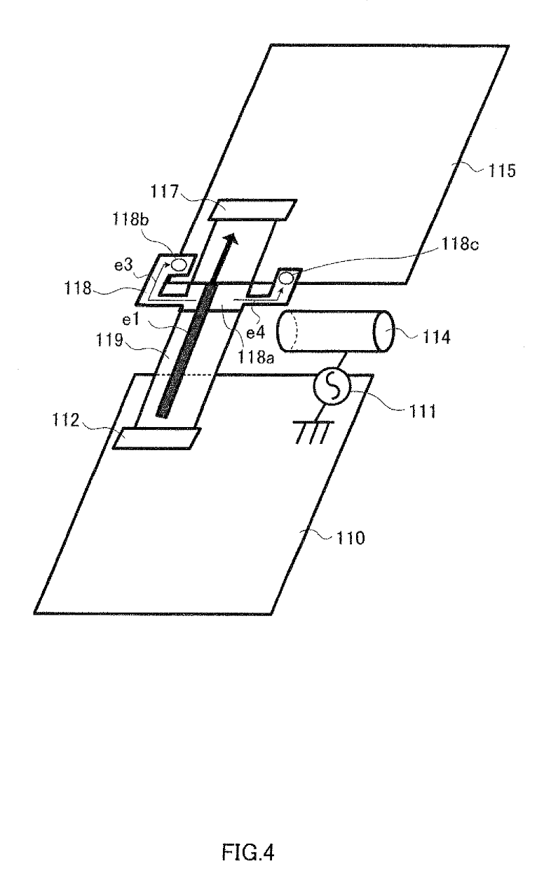

Next, the flow of the current in portable radio device 100 will be described with reference to FIGS. 2 to 4. FIG. 2 is a perspective view illustrating the main part of portable radio device 100 for describing the flow of the antenna current when conductive element 118 is not provided. FIG. 3 is a side view illustrating the main part of portable radio device 100 describing the flow of the antenna current when conductive element 118 is not provided. FIG 4 is a perspective view illustrating the main part of portable radio device 100 describing the flow of the antenna current when conductive element 118 is provided. In FIGS. 2 to 4, the same components as FIG. 1 will be assigned the same reference numerals.

In FIGS. 2 and 3, an antenna current e1 in signal line 119 flows to second circuit board 115 from first circuit board 110.

Meanwhile, connector 117 is electrically connected to second circuit board 115, so that reverse-phase current e2 having a phase reverse to that of antenna current e1 flows in a part of second circuit board 115 vertically overlapped with signal line 119. Therefore, antenna current e1 is canceled out by reverse-phase current e2 so that the antenna performance is deteriorated.

In contrast, as illustrated in FIG. 4, a part of antenna current e1 may be distributed to conductive element 118 by providing conductive element 118. If connection ends 118b and 118c are connected to the end of second circuit board 115, antenna currents e3 and e4 distributed to conductive element 118 may flow upwardly to be the same phase as that of antenna current e1 in second circuit board 115. Antenna current e1 in a portion of signal line 119 overlapped with second circuit board 115 may be reduced by distributing the current to conductive element 118 in comparison with the related art. As a result, it is possible to suppress reverse-phase current e2 flowing through second circuit board 115 and antenna current e1 canceled out by reverse-phase current e2.

Thus, according to the present embodiment, it is possible to prevent deterioration of the antenna performance due to the reverse-phase current by providing the conductive element to distribute the antenna current flowing through the signal line. According to the present embodiment, since the conductive element is provided integrally with the waterproof packing, it is possible to firmly connect the conductive element to the signal line using the elastic force of the waterproof packing and improve electrical connection between the conductive element and the signal line. In addition, according to the present embodiment, since the connection portion between the conductive element and the signal line is formed wider than other portions, it is possible to improve the electrical connection between the conductive element and the signal line. In addition, according to the present embodiment, since the conductive element is formed of a printed pattern of FPC, it is possible to improve adhesion between the conductive element made of a flexible material and the signal line and electrical connection between the conductive element and the signal line. In addition, according to the present embodiment, since the waterproof packing and the conductive element are integrally formed, it is possible to simplify installation of the conductive element to the second casing and reduce the manufacturing cost.

### Embodiment 2

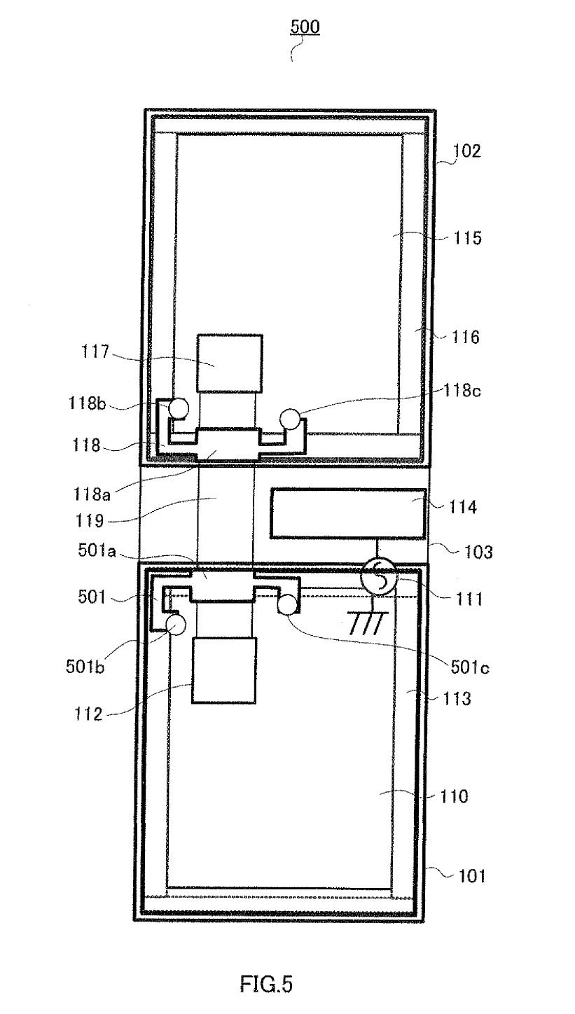

FIG. 5 is a plan view illustrating portable radio device 500 in an opened state according to Embodiment 2 of the present invention.

Portable radio device 500 of FIG. 5 includes further conductive element 501 in addition to portable radio device 100 according to Embodiment 1 of FIG. 1. In FIG. 5, the same components in FIG. 1 will be assigned the same reference numerals and overlapping explanation will be omitted.

Portable radio device 500 is mainly formed by first casing 101, second casing 102, hinge section 103, and signal line 119.

First casing 101 includes first circuit board 110, power feeding section 111, connector 112, waterproof packing 113, and conductive element 501. Hereinafter, the present embodiment will describe components different from the above Embodiment 1 in detail.

First circuit board 110 is provided across substantially the entire surface of the inner side of first casing 101. Connector 112 is mounted on first circuit board 110 to electrically connect first circuit board 110 to second circuit board 115 through connector 112, signal line 119, and connector 117. First circuit board 110 is electrically connected to conductive element 501 in the end of hinge section 103 side.

Conductive element 501 is made of, for example, a printed pattern of FPC, and is provided integrally with waterproof packing 113 in first casing 101. Furthermore, conductive element 501 is electrically connected to signal line 119 on the mating surface used to fit two cases of first casing 101. Conductive element 501 is electrically connected to the end of first circuit board 110. Conductive element 501 includes wide-width section 501a that is formed to have a wide width and electrically connected to signal line 119, and connection ends 501b and 501c that horizontally extended from wide-width section 501a and are electrically connected to the end of first circuit board 110.

Waterproof packing 113 has an annular shape and is provided in the mating surface used to fit two cases of first casing 101. Waterproof packing 113 hermitically seals the gap between the two cases formed when the two cases are fitted. Waterproof packing 113 is formed of a material having an elastic force that can reliably and hermetically seal the gap between two fitted cases. Waterproof packing 113 is provided integrally with the conductive element 501, and conductive element 501 is firmly connected to signal line 119 by pressedly bonding conductive element 501 and signal line 119.

Signal line 119 made of, for example, FPC is electrically connected to first circuit board 110 through connector 112, and is electrically connected to second circuit board 115 through connector 117. Specifically, signal line 119 is electrically connected to first and second circuit boards 110 and 115. Signal line 119 is electrically connected to conductive elements 118 and 501. In this case, conductive element 118 may be electrically connected to signal line 119 directly or equivalently using a capacitive coupling through a capacitor. Similarly, conductive element 501 may be electrically connected to signal line 119 directly or equivalently using a capacitive coupling through a capacitor.

Hereinbefore, the configuration of portable radio device 500 has been described.

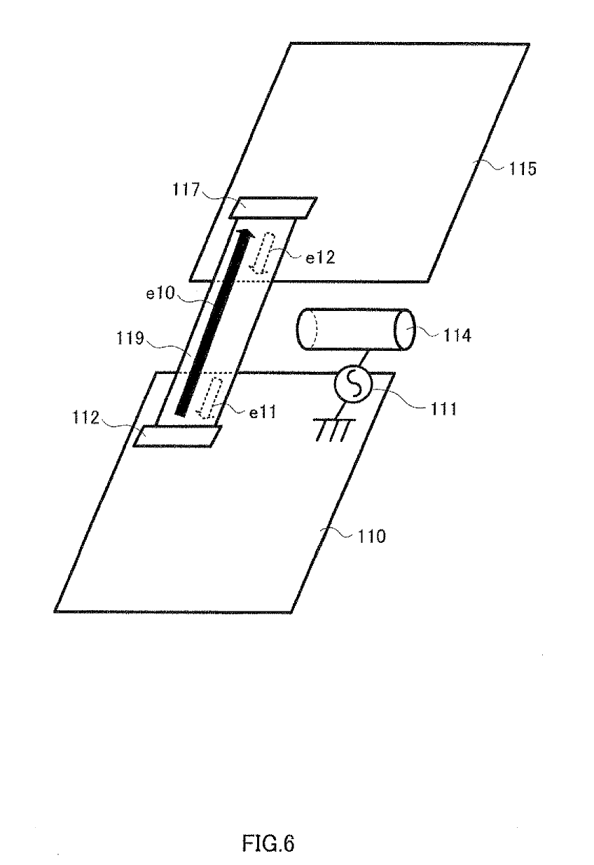

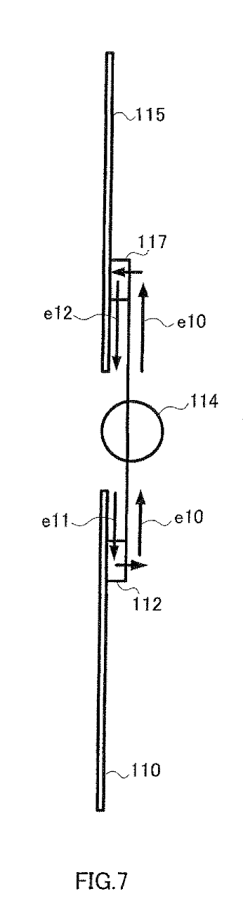

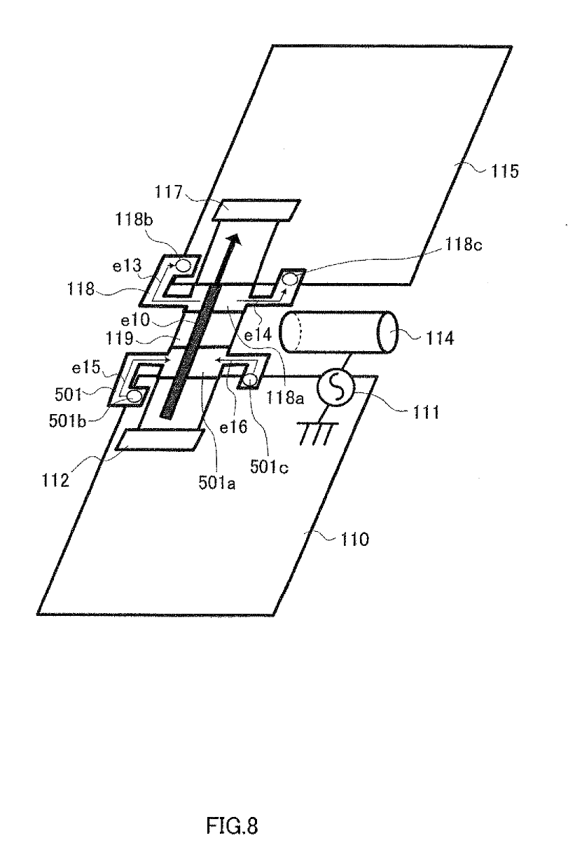

Next, the flow of the current in portable radio device 500 will be described with reference to FIGS. 6 to 8. FIG. 6 is a perspective view illustrating the main part of portable radio device 500 for describing the flow of the antenna current when conductive elements 118 and 501 are not provided. FIG. 7 is a side view illustrating the main part of portable radio device 500 for describing the flow of the antenna current when the conductive elements 118 and 501 are not provided. FIG. 8 is a perspective view illustrating the main part of portable radio device 500 for describing the flow of the antenna current when the conductive elements 118 and 501 are provided. In FIGS. 6 to 8, the same components as FIG. 5 will be assigned the same reference numerals.

In FIGS. 6 and 7, antenna current e10 in signal line 119 flows in a direction from first circuit board 110 to second circuit board 115.

Meanwhile, connector 112 is electrically connected to first circuit board 110, so that reverse-phase current e11 having a phase reverse to that of antenna current e10 flows in a part of first circuit board 110 vertically overlapped with signal line 119. Similarly, connector 117 is electrically connected to second circuit board 115, so that reverse-phase current e12 having a phase reverse to that of antenna current e10 flows in a part of second circuit board 115 vertically overlapped with signal line 119.

Therefore, antenna current e10 is canceled out by reverse-phase currents e11 and e12, so that the antenna performance is deteriorated.

In contrast, as illustrated in FIG. 8, a part of antenna current e10 may be distributed to conductive element 118 by providing conductive element 118. If connection ends 118b and 118c are connected to end of second circuit board 115, antenna currents e13 and e14 distributed to conductive element 118 may flow upwardly with the same phase as that of antenna current e10 in second circuit board 115. Antenna current e10 in a portion of signal line 119 overlapped with second circuit board 115 may be reduced by distributing antenna current e10 to conductive element 118 in comparison with the related art. As a result, it is possible to suppress reverse-phase current e12 flowing through second circuit board 115, so that antenna current e10 is prevented from being canceled out by reverse-phase current e12.

In the present embodiment of FIG. 8, conductive element 501 is provided, and connection ends 501b and 501c are connected to the end of first circuit board 110. Therefore, reverse-phase current e11 flowing to a portion vertically overlapped with signal line 119 of first circuit board 110 can flow to conductive element 501 (currents e15 and e16). As a result, currents e15 and e16 flowing to conductive element 501 can flow upwardly with the same phase as that of antenna current e10 of signal line 119, so that it is possible to prevent antenna current e10 from being canceled out by reverse-phase current e11.

In this manner, according to the present embodiment, in addition to the effects of Embodiment 1, the conductive element connecting the first circuit board of the first casing is provided, so that it is possible to further prevent the antenna current from being canceled out by the reverse-phase current in the portion where the signal line and the first circuit board are vertically overlapped and improve the antenna performance.

### Embodiment 3

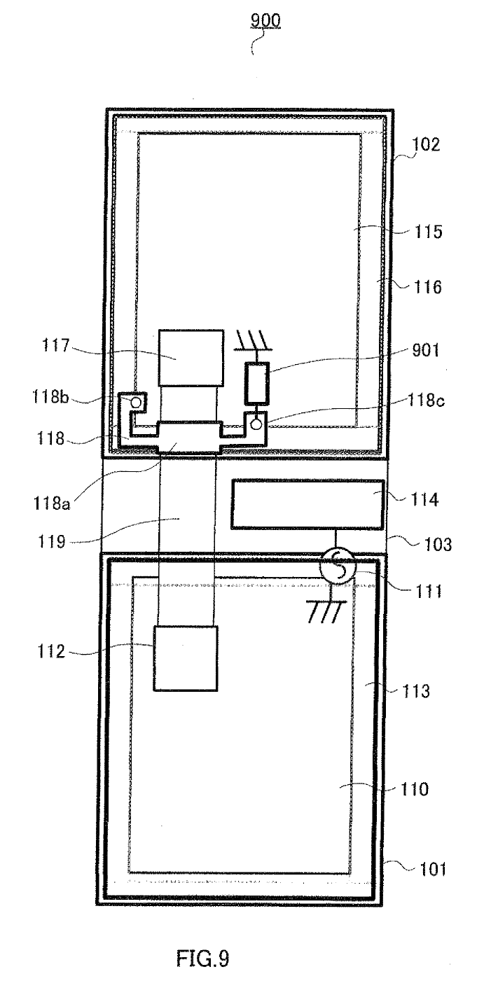

FIG. 9 is a plan view illustrating portable radio device 900 in an opened state according to Embodiment 3 of the present invention.

Portable radio device 900 illustrated in FIG. 9 further includes reactance element 901 in addition to portable radio device 100 according to Embodiment 1 of FIG. 1. In FIG. 9, the same components in FIG. 1 will be assigned the same reference numerals and overlapping explanation will be omitted.

Portable radio device 900 is mainly formed by first casing 101, second casing 102, hinge section 103, and signal line 119.

Second casing 102 includes circuit board 115, waterproof packing 116, connector 117, conductive element 118, and reactance element 901. Hereinafter, the present embodiment will describe components different from the above Embodiment 1 in detail.

Second circuit board 115 is provided substantially the entire inner side of second casing 102. Connector 117 is mounted on second circuit board 115, and second circuit board 115 is electrically connected to first circuit board 110 through connector 112, signal line 119, and connector 117. Second circuit board 115 is electrically connected to conductive element 118 in the end of hinge section 103 side. Reactance element 901 is mounted on second circuit board 115, and conductive element 118 is grounded through reactance element 901.

Conductive element 118 made of, for example, a printed pattern of FPC is provided integrally with waterproof packing 116 in second casing 102. Furthermore, conductive element 118 is electrically connected to signal line 119 in the mating surface used to fit two cases of second casing 102. Conductive element 118 is electrically connected to the end of second circuit board 115, and is grounded to second circuit board 115 through reactance element 901. Conductive element 118 includes: wide-width section 118a that is formed to have a wide width and is electrically connected to signal line 119; connection end 118b that horizontally extends from wide-width section 118a and is electrically connected to the end of second circuit board 115; and connection end 118c that horizontally extends in a direction opposite to the extending direction of connection end 118b from wide-width section 118a, is electrically connected to reactance element 901, and is grounded to second circuit board 115 through reactance element 901.

Reactance element 901 is provided in second circuit board 115. Reactance element 901 is connected in series between second circuit board 115 and conductive element 118.

In addition, the flow of the antenna current in portable radio device 900 is the same as Embodiment 1 described above and overlapping explanation will be omitted.

Thus, according to the present embodiment, in addition to the effects of above Embodiment 1, the conductive element is grounded through the reactance, so that it is possible to control the antenna current depending on the use frequency or the length of the signal line and further improve the antenna performance.

Although the conductive element is provided only in the second casing according to the present embodiment, the present invention is not limited thereto and the conductive element may be provided in the first casing in addition to the second casing, and the conductive element provided in the first casing may be grounded to the first circuit board through the reactance element.

### Embodiment 4

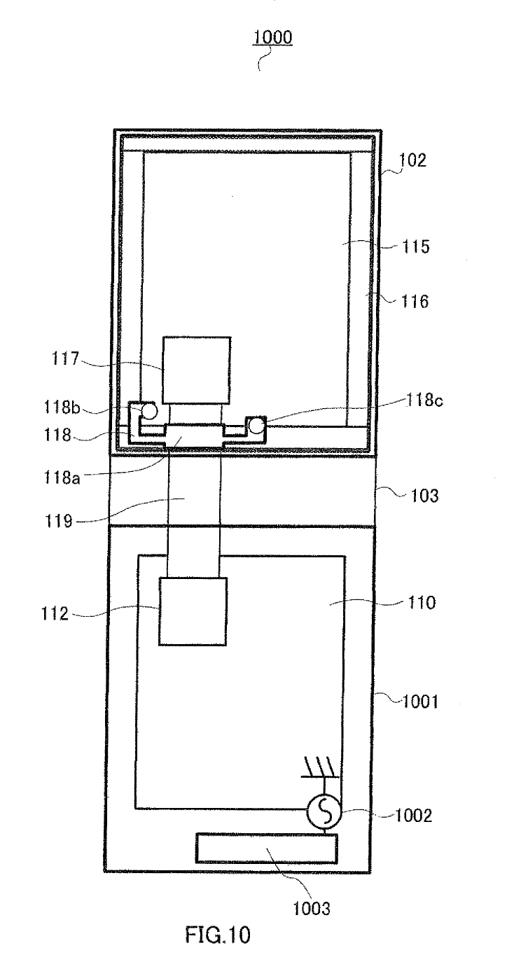

FIG. 10 is a plan view illustrating portable radio device 1000 in an opened state according to Embodiment 4 of the present invention.

Portable radio device 1000 of FIG. 10 includes antenna 1003 excluding waterproof packing 113 in comparison with portable radio device 100 according to Embodiment 1 of FIG. 1; first casing 101, is substituted with first casing 1001; and power feeding section 111 is substituted with power feeding section 1002. In FIG. 10, the same components in FIG. 1 will be assigned the same reference numerals and overlapping explanation will be omitted.

Portable radio device 1000 is mainly formed by first casing 1001, second casing 102, hinge section 103, and signal line 119.

First casing 1001 includes first circuit board 110, connector 112, power feeding section 1002, and antenna 1003. Hereinafter, the present embodiment will describe components different from the above Embodiment 1 in detail.

First casing 1001 has a substantially box shape and a rectangular shape in plan view, and is foldably connected to second casing 102 through hinge section 103. Specifically, the state of first casing 1001 changes from a closed state (not illustrated) in which first casing 1001 and second casing 102 are vertically overlapped to an opened state of FIG. 10 or from the opened state of FIG. 10 to the closed state. First casing 1001 has first circuit board 110 therein. First casing 1001 includes antenna 1003 in the downward end (bottom of FIG 10).

Second casing 102 has a substantially box shape formed by fitting two cases at an annular mating surface and is foldably connected to first casing 1001 through hinge section 103. Specifically, the state of second casing 102 changes from a closed state (not illustrated) in which first casing 1001 and second casing 102 are vertically overlapped to an opened state of FIG. 1 or from the opened state of FIG. 1 to the closed state. Second casing 102 has second circuit board 115 therein. Second casing 102 includes waterproof packing 116 provided in the mating surface used to fit two cases and interposed between two cases and conductive element 118 integrated with waterproof packing 116 in hinge section 103 side.

Hinge section 103 connects first casing 1001 and second casing 102 in a rotatable manner.

First circuit board 110 is provided across substantially the entire surface of the inner side of first casing 1001. First circuit board 110 includes power feeding section 1002. Connector 112 is mounted on first circuit board 110 to electrically connect first circuit board 110 to second circuit board 115 through connector 117, signal line 119, and connector 112.

Power feeding section 1002 is provided in first circuit board 110 and feeds electricity to antenna 1003 to excite antenna 1003.

Antenna 1003 receives electricity fed from power feeding section 1002 and resonates at a desired frequency.

The flow of the antenna current in portable radio device 1000 is the same as Embodiment 1 described above and overlapping explanation will be omitted.

In this manner, according to the present embodiment, it is possible to obtain the effects that is the same as Embodiment 1 using the portable radio device in which the antenna is arranged in the downward end of the first casing.

Although the conductive element is directly connected to the end of the circuit board according to the present embodiment, the present invention is not limited thereto, and similarly to Embodiment 3 described above, the conductive element may be grounded to the second circuit board through the reactance element. Although the waterproof packing is not provided in the first casing according to the present embodiment, the present invention is not limited thereto, the waterproof packing may be provided in the first casing, and the conductive element electrically connected to the end of the first circuit board may be provided in the waterproof packing provided in the first casing.

Although the waterproof packing is used in Embodiments 1 to 4 described above, the present invention is not limited thereto, and any purpose packing having an excellent sealing property such as a dustproof packing may be used instead of the waterproof packing. Although description has been made for a folder type portable radio device in Embodiments 1 to 4, the present invention is not limited thereto, and the present invention may be applied to any type of portable radio devices such as a slide type portable radio device. Although description has been made for the portable radio device using two casings in Embodiments 1 to 4, the present invention is not limited thereto, and the present invention may be applied to the portable radio device using casings with an arbitrary number equal to or more than three.

The disclosures of Japanese Patent Application No 2009484693 filed on Aug. 7, 2009, including the specification, drawings and abstract, is incorporated herein by reference in its entirety.

### INDUSTRIAL APPLICABILITY

The present invention is suitable especially for the portable radio device that is equipped with a plurality of casings and has a waterproof structure.

1. A portable radio device that has two or more box-shaped casings that are formed by fitting two cases at a mating surface that is annular, the portable radio device comprising:
a first circuit board that is provided in a first casing;
a second circuit board that is provided in a second casing;
a signal line that electrically connects the first circuit board and the second circuit board;
a first packing that is annular and is interposed between a first case and a second case on the mating surface between the first case and the second case forming the second casing; and
a first conductive element that is integrated with the first packing, electrically connected to an end of the second circuit board, and electrically connected to the signal line on the mating surface.

2. The portable radio device according to claim 1, further comprising a second packing that is annular and is interposed between a third case and a fourth case on a mating surface between the third and fourth cases of the first casing; and
a second conductive element that is integrated with the second packing, electrically connected to an end of the first circuit board, and electrically connected to the signal line on the mating surface.

3. The portable radio device according to claim 1, wherein the first conductive element is electrically connected to the end of the second circuit board through a reactance element.

4. The portable radio device according to claim 1, further comprising:
a hinge section that rotatably connects the first casing and the second casing;
a power feeding section that is provided in the first circuit board; and
an antenna that is provided in the hinge section and is fed power from the power feeding section.

5. The portable radio device according to claim 1, further comprising:
a power feeding section that is provided in the first circuit board; and
an antenna that is provided in the first casing and is fed power from the power feeding section.
